(19) United States
(12) Patent Application Publication
(10) Pub. No.: US 2023/0200132 A1
(43) Pub. Date: Jun. 22, 2023

(54) ELECTROLUMINESCENT DISPLAY DEVICE

(71) Applicant: LG Display Co., Ltd., Seoul (KR)

(72) Inventor: JoonWon PARK, Paju-si (KR)

(21) Appl. No.: 17/945,660

(22) Filed: Sep. 15, 2022

(30) Foreign Application Priority Data
Dec. 22, 2021 (KR) 10-2021-0185317

(51) Int. Cl. H01L 27/32; H01L 29/786

(52) U.S. Cl. CPC H01L 27/3262; H01L 27/3218; H01L 27/3246; H01L 29/7869

(57) ABSTRACT

An electroluminescent display device according to an embodiment of the present disclosure may include a substrate divided into a plurality of sub-pixels having an emission area and a non-emission area, an oxide thin film transistor disposed on the substrate, a planarization layer disposed on the oxide thin film transistor, an anode disposed on the planarization layer in the emission area, a bank disposed on the anode and the planarization layer and having an opening exposing a portion of the anode, a first hydrogen adsorption layer disposed on the planarization layer in the non-emission area, a spacer disposed on the first hydrogen adsorption layer and a light emitting structure and a cathode disposed on the exposed anode, the bank, and the spacer. It is possible to improve characteristics and reliability of the thin film transistor by blocking an inflow of hydrogen into the oxide thin film transistor.

### CROSS REFERENCE TO RELATED APPLICATIONS

This application claims the benefit of and priority to Korean Patent Application No. 10-2021-0185317, filed on Dec. 22, 2021, in the Republic of Korea, which is herein incorporated by reference in its entirety.

### BACKGROUND

### Technical Field

The present disclosure relates to an electroluminescent display device, and more particularly, to an electroluminescent display device using an oxide thin film transistor.

### Description of the Related Art

Recently, as our society advances toward an information-oriented society, the field of display devices for visually expressing an electrical information signal has rapidly advanced. Various display devices having excellent performance in terms of thinness, lightness, and low power consumption, are being developed correspondingly.

Representative display devices include a liquid crystal display device (LCD), an electro-wetting display device (EWD), an organic light emitting display device (OLED), and the like.

Among these display devices, an electroluminescent display device including an organic light emitting display device is a self-emission display device, and can be manufactured to be light and thin since it does not require a separate light source, unlike a liquid crystal display device having a separate light source. In addition, the electroluminescent display device has advantages in terms of power consumption due to a low voltage driving, and is excellent in terms of a color implementation, a response speed, a viewing angle, and a contrast ratio (CR). Therefore, electroluminescent display devices are expected to be utilized in various fields.

An electroluminescent display device may be constructed by disposing a light emitting layer using an organic material between two electrodes that may be referred to as an anode and a cathode. Then, when holes from the anode are injected into the light emitting layer and electrons from the cathode are injected into the light emitting layer, the injected electrons and holes may recombine with each other and emit light. When an electron in an exciton recombines with a hole, the exciton disappears and the energy of the exciton may be converted into light.

### BRIEF SUMMARY

An aspect of the present disclosure is to provide an electroluminescent display device in which an inflow of hydrogen into an oxide thin film transistor is prevented.

An electroluminescent display device according to an example embodiment of the present disclosure may include a substrate divided into a plurality of sub-pixels having an emission area and a non-emission area, an oxide thin film transistor disposed on the substrate, a planarization layer disposed on the oxide thin film transistor, an anode disposed on the planarization layer in the emission area, a bank disposed on the anode and the planarization layer and having an opening exposing a portion of the anode, a first hydrogen adsorption layer disposed on the planarization layer in the non-emission area, a spacer disposed on the first hydrogen adsorption layer and a light emitting structure and a cathode disposed on the exposed anode, the bank, and the spacer.

Other detailed matters of the example embodiments are included in the detailed description and the drawings.

According to the present disclosure, an inflow of hydrogen into an oxide thin film transistor is prevented by forming a hydrogen adsorption layer in a non-emissive area other than an emission area where an anode is positioned, so that characteristics and reliability of the oxide thin film transistor can be improved.

According to the present disclosure, it is possible to improve light extraction efficiency by converting a direction of laterally leaking light from a light emitting structure into an upward direction using a hydrogen adsorption layer.

The effects according to the present disclosure are not limited to the contents exemplified above, and more various effects are included in the present specification.

### BRIEF DESCRIPTION OF THE SEVERAL VIEWS OF THE DRAWINGS

FIG. 1 is a block diagram of an electroluminescent display device according to a first example embodiment of the present disclosure.

FIG. 2 is a circuit diagram of a sub-pixel of the electroluminescent display device of FIG. 1.

FIG. 3 is a plan view illustrating one pixel structure of the electroluminescent display device of FIG. 1.

FIG. 4 is a cross-sectional view taken along III-III′ of FIG. 3.

FIGS. 5A and 5B are tables respectively showing reliability results of a display panel according to a thickness and an area of a hydrogen adsorption layer.

FIG. 6 is a plan view illustrating a pixel structure according to a second example embodiment of the present disclosure.

FIG. 7 is a cross-sectional view taken along VI-VI′ of FIG. 6.

FIG. 8 is a cross-sectional view of an electroluminescent display device according to a third example embodiment of the present disclosure.

FIG. 9 is a cross-sectional view of an electroluminescent display device according to a fourth example embodiment of the present disclosure.

FIG. 10 is a cross-sectional view of an electroluminescent display device according to a fifth example embodiment of the present disclosure.

### DETAILED DESCRIPTION

Advantages and characteristics of the present disclosure and a method of achieving the advantages and characteristics will be clear by referring to example embodiments described below in detail together with the accompanying drawings. However, the present disclosure is not limited to the example embodiments disclosed herein but may be implemented in various forms. The example embodiments are provided by way of example only so that those skilled in the art can fully understand the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, example embodiments of the present disclosure will be described in detail with reference to accompanying drawings.

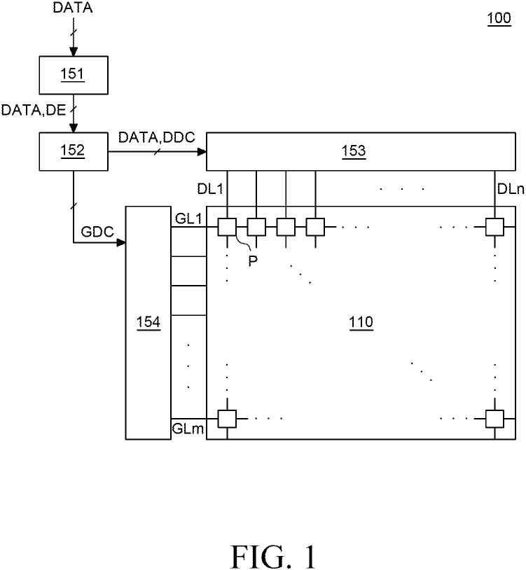

FIG. 1 is a block diagram of an electroluminescent display device according to a first example embodiment of the present disclosure.

Referring to FIG. 1, an electroluminescent display device 100 according to the first example embodiment of the present disclosure may include an image processor 151, a timing controller 152, a data driver 153, a gate driver 154, and a display panel 110.

The image processor 151 may output a data signal DATA and a data enable signal DE through a data signal DATA supplied from the outside.

The image processor 151 may output one or more of a vertical synchronization signal, a horizontal synchronization signal, and a clock signal in addition to the data enable signal DE.

The timing controller 152 receives the data signal DATA together with the data enable signal DE or driving signals including the vertical synchronization signal, the horizontal synchronization signal, and the clock signal from the image processor 151. The timing controller 152 may output a gate timing control signal GDC for controlling an operation timing of the gate driver 154 and a data timing control signal DDC for controlling an operation timing of the data driver 153 based on the driving signals.

The data driver 153 samples and latches the data signal DATA supplied from the timing controller 152 in response to the data timing control signal DDC supplied from the timing controller 152, and converts the data signal DATA into a gamma reference voltage to thereby output it. The data driver 153 may output the data signal DATA through data lines DL1 to DLn.

The gate driver 154 outputs a gate signal while shifting a level of the gate voltage in response to the gate timing control signal GDC supplied from the timing controller 152. The gate driver 154 may output the gate signal through gate lines GL1 to GLm.

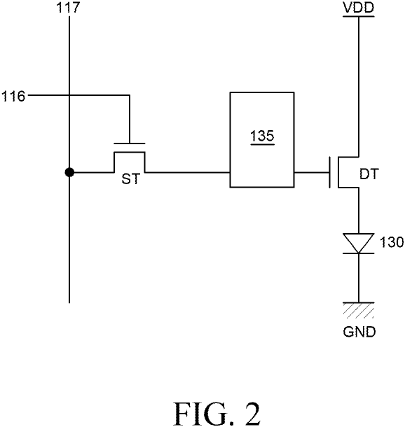

The display panel 110 may display an image while sub-pixels P emit light in response to the data signal DATA and the gate signal supplied from the data driver 153 and the gate driver 154. A detailed structure of the sub-pixel P will be described in detail in FIG. 2 to FIG. 4.

FIG. 2 is a circuit diagram of a sub-pixel of the electroluminescent display device of FIG. 1.

Referring to FIG. 2, the sub-pixel of the electroluminescent display device according to the first example embodiment of the present disclosure may include a switching transistor ST, a driving transistor DT, a compensation circuit 135, and a light emitting element 130.

The light emitting element 130 may operate to emit light according to a driving current that is formed by the driving transistor DT.

The switching transistor ST may perform a switching operation such that a data signal supplied through a data line 117 in response to the gate signal supplied through a gate line 116 is stored as a data voltage in a capacitor.

In addition, the driving transistor DT may operate such that a constant driving current flows between a high potential power line VDD and a low potential power line GND in response to the data voltage stored in the capacitor.

The compensation circuit 135 is a circuit for compensating for a threshold voltage or the like of the driving transistor DT, and the compensation circuit 135 may include one or more thin film transistors and capacitors. A configuration of the compensation circuit 135 may vary according to a compensation method.

It is illustrated that the sub-pixel shown in FIG. 2 is configured to have a 2T(Transistor)1C (Capacitor) structure including the switching transistor ST, the driving transistor DT, the capacitor not depicted, and the light emitting element 130. However, the sub-pixel may have various structures, such as 3T1C, 4T2C, 5T2C, 6T1C, 6T2C, 7T1C and 7T2C structures when the compensation circuit 135 is added thereto.

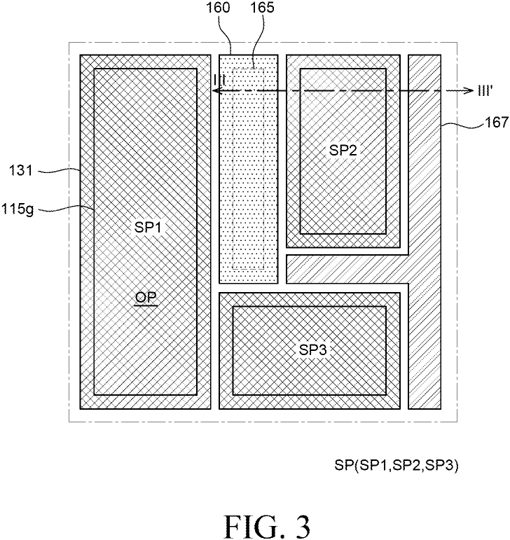

FIG. 3 is a plan view illustrating one pixel structure of the electroluminescent display device of FIG. 1.

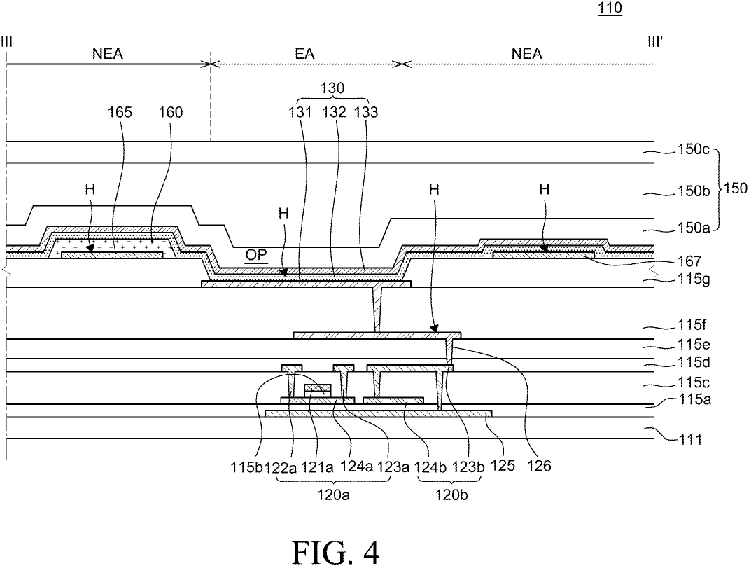

FIG. 4 is a cross-sectional view taken along III-III′ of FIG. 3.

In FIG. 3, only an anode 131 and banks 115g are illustrated among components of the light emitting element 130 for convenience of explanation. The banks 115g may be disposed in remaining areas other than an area exposed by an opening OP.

The electroluminescent display device according to the first example embodiment of the present disclosure may include a display panel that is divided into an active area and a non-active area.

The display panel may comprise a panel for displaying an image to a user.

In the display panel, display elements for displaying an image, a driving element for driving the display elements, and lines for transmitting various signals to the display elements and the driving element may be disposed. The display element may be defined differently according to a type of the display panel. For example, when the display panel is an organic light emitting display panel, the display element may be an organic light emitting element including an anode, an organic light emitting layer, and a cathode.

Hereinafter, it is described assuming that the display panel is an organic light emitting display panel, but the display panel 110 is not limited to the organic light emitting display panel.

The active area is an area in which an image is displayed on the display panel.

A plurality of sub-pixels SP constituting a plurality of pixels and circuits for driving the plurality of sub-pixels SP may be disposed in the active area. In some cases, the plurality of sub-pixels SP are minimum units constituting the active area, and the display element may be disposed in each of the plurality of sub-pixels SP, and the plurality of sub-pixels SP may constitute the pixel. For example, a light emitting element including the anode 131, an organic light emitting layer, and a cathode may be disposed in each of the plurality of sub-pixels SP, but is not limited thereto. The circuit for driving the plurality of sub-pixels SP may include a driving element, lines and the like. For example, the circuit may be formed of a thin film transistor, a storage capacitor, a gate line, a data line, and the like, but is not limited thereto.

That is, the plurality of sub-pixels SP may comprise individual units that emit light, and the light emitting element may be disposed in each of the plurality of sub-pixels SP. The plurality of sub-pixels SP may include a first sub-pixel SP1, a second sub-pixel SP2, and a third sub-pixel SP3 that emit light of different colors. For example, the first sub-pixel SP1 may be a green sub-pixel, the second sub-pixel SP2 may be a red sub-pixel, and the third sub-pixel SP3 may be a blue sub-pixel. However, the present disclosure is not limited thereto.

A plurality of the first sub-pixels SP1 may be disposed in a plurality of columns. That is, the plurality of first sub-pixels SP1 may be disposed in the same column. In addition, a plurality of the second sub-pixels SP2 and a plurality of the third sub-pixels SP3 may be disposed between the plurality of respective columns in which the plurality of first sub-pixels SP1 are disposed. For example, the plurality of first sub-pixels SP1 may be disposed in one column, and the second sub-pixels SP2 and the third sub-pixels SP3 may be disposed together in a column adjacent thereto. In addition, the plurality of second sub-pixels SP2 and the plurality of third sub-pixels SP3 may be alternately disposed in the same column. However, the present disclosure is not limited thereto.

In addition, in the present disclosure, although it is described that the plurality of sub-pixels SP include the first sub-pixels SP1, the second sub-pixels SP2, and the third sub-pixels SP3, the arrangement, number, and color combination of the plurality of sub-pixels SP may be variously changed according to design, and are not limited thereto.

For example, high potential power lines VDD that extend in a column direction are disposed between the plurality of sub-pixels SP. A plurality of the high potential power lines VDD are lines that transmit high potential power (e.g., 3.3 V) signals to each of the plurality of sub-pixels SP. Each of the plurality of high potential power lines VDD may be disposed between the first sub-pixel SP1 and the second sub-pixel SP2 and between the first sub-pixel SP1 and the third sub-pixel SP3. However, the present disclosure is not limited thereto.

A plurality of data lines 117 that extend in the column direction in the same manner as the plurality of high potential power lines VDD may be disposed. The plurality of data lines 117 are lines that transmit data signals to each of the plurality of sub-pixels SP. For example, each of the data lines 117 may be disposed between the second sub-pixel SP2 and the high potential power line VDD and between the third sub-pixel SP3 and the high potential power line VDD or may be disposed between the first sub-pixel SP1 and the high potential power line VDD. However, the present disclosure is not limited thereto.

In addition, a plurality of scan lines (gate lines) 116 that extend in a row direction are disposed. The plurality of scan lines 116 are lines that transmit scan signals to each of the plurality of sub-pixels SP. The plurality of scan lines 116 include first scan lines and second scan lines. The first scan line may be disposed to extend in the row direction between the second sub-pixel SP2 and the third sub-pixel SP3, and the second scan line may cross the first sub-pixel SP1 and be disposed to extend in the row direction. However, the present disclosure is not limited thereto.

A plurality of initialization signal lines that extend in the row direction in the same manner as the plurality of scan lines 116 may be disposed between the plurality of sub-pixels SP. The plurality of initialization signal lines are lines that transmit initialization signals to each of the plurality of sub-pixels SP. Each of the plurality of initialization signal lines may be disposed between the second sub-pixel SP2 and the third sub-pixel SP3. The plurality of initialization signal lines may be disposed between the first scan lines and the second scan lines. However, the present disclosure is not limited thereto.

A plurality of emission control signal lines that extend in the row direction in the same manner as the plurality of scan lines 116 may be disposed. The plurality of emission control signal lines are lines that transmit emission control signals to each of the plurality of sub-pixels SP. The plurality of emission control signal lines may be disposed to be adjacent to the plurality of second scan lines. In addition, the plurality of emission control signal lines may be disposed to cross the first sub-pixels SP1 and extend in the row direction. The second scan lines may be disposed between the plurality of emission control signal lines and the plurality of initialization signal lines.

The plurality of lines may be classified into direct current (DC) lines that transmit a DC signal and alternating current (AC) lines that transmit an AC signal. Among the plurality of lines, the high potential power line VDD and the initialization signal line that transmit the high potential power signal or the initialization signal which is a DC signal, may be included in the DC lines. Also, among the plurality of lines, the scan line 116 and the data line 117 that transmit the scan signals and the data signal may, in some cases, be included in the AC lines or be classified as lines in which an applied voltage may vary over time.

A plurality of spacers 160 may be disposed between the plurality of sub-pixels SP. When the light emitting elements 130 are formed in the plurality of sub-pixels SP, a fine metal mask (FMM), which is a deposition mask, may be used. In this case, the plurality of the spacers 160 may be disposed to prevent damage that may be caused by contact with the deposition mask and to maintain a constant distance between the deposition mask and a substrate.

Meanwhile, the non-active area is an area where no image is displayed.

The active area and the non-active area may have a shape suitable for designing an electronic apparatus on which the electroluminescent display device is mounted. For example, an example shape of the active area may be a pentagonal shape, a hexagonal shape, a circular shape, or an oval shape, in addition to a quadrangular shape.

Various lines and circuits for driving the light emitting element of the active area may be disposed in the non-active area. For example, in the non-active area, driver ICs such as a gate driver IC and a data driver IC or link lines for transmitting signals to the plurality of sub-pixels SP and circuits of the active area may be disposed, but are not limited thereto.

The gate driver IC may be formed independently of the display panel and may be configured in a form capable of being electrically connected to the display panel in various manners, but may be configured in a method of a gate in panel (GIP) that is mounted in the display panel.

The electroluminescent display device may include various additional elements for generating various signals or driving the pixels in the active area. The additional elements for driving the pixels may include an inverter circuit, a multiplexer, an electro-static discharge (ESD) circuit, and the like. The electroluminescent display device may include additional elements associated with functions other than driving the pixels. For example, the electroluminescent display device may include additional elements that provide a touch sensing function, a user authentication function (e.g., fingerprint recognition), a multi-level pressure sensing function, a tactile feedback function, and the like. Such additional element may be positioned in the non-active area and/or in an external circuit connected to a connection interface.

Meanwhile, excellent characteristics of the display panel are secured by using an oxide thin film transistor having characteristics of high mobility and low off current.

That is, when the oxide thin film transistor is used, it is advantageous in manufacturing of a large-area display panel as well as in terms of low power, stability, and cost reduction. However, the oxide thin film transistor has a defect in that initial characteristics thereof vary due to hydrogen generated inside the display panel. For example, a threshold voltage Vth may be shifted in a negative direction (negatively shifted) by hydrogen.

In particular, in a top emission structure for high resolution of an electroluminescent display device, a thin film encapsulation (TFE) structure for blocking moisture needs to be applied as an encapsulation structure because a light emitting surface should be transparent. In the TFE structure, during reliability evaluation, an underlying oxide thin film transistor is affected by hydrogen generated from primary and secondary protective layers formed of inorganic insulating layers, and thus, defects of increases in luminance and bright spots may occur. That is, in an existing TFE structure, primary and secondary protective layers are formed of silicon nitride having excellent moisture permeability prevention performance to protect a light emitting element from external moisture and oxygen. Since the primary and secondary protective layers contain a large amount of hydrogen in the layers, the hydrogen may diffuse during reliability evaluation, thereby changing characteristics of the oxide thin film transistor.

Accordingly, the present disclosure is characterized in that characteristics and reliability of the thin film transistor are improved by blocking an inflow of hydrogen into the oxide thin film transistor.

To this end, the first example embodiment of the present disclosure is characterized in that a plurality of hydrogen adsorption layers 165 and 167 are disposed between the plurality of sub-pixels SP.

In this case, for example, the hydrogen adsorption layers 165 and 167 may include a first hydrogen adsorption layer 165 disposed between the first sub-pixel SP1 and the second sub-pixel SP2 and a second hydrogen adsorption layer 167 disposed between the third sub-pixel SP3 and the first sub-pixel SP1.

The first hydrogen adsorption layer 165 may be disposed between the first sub-pixel SP1 and the second sub-pixel SP2 in the column direction, and the second hydrogen adsorption layer 167 may be disposed between the second sub-pixel SP2 and the first sub-pixel SP1 in the column direction, while a portion of the second hydrogen adsorption layer 167 may extend between the second sub-pixel SP2 and the third sub-pixel SP3 in the row direction. However, the present disclosure is not limited thereto.

The first hydrogen adsorption layer 165 may be disposed under the spacer 160.

As described above, in the first example embodiment of the present disclosure, the hydrogen adsorption layers 165 and 167 are formed on the banks 115g except for an area where the anode 131 is positioned to thereby block an inflow of hydrogen into the oxide thin film transistor, so that characteristics and reliability of the oxide thin film transistor can be improved.

Specifically, referring to FIG. 4, first and second thin film transistors 120a and 120b, the light emitting element 130, and an encapsulation layer 150 may be formed in the active area of a substrate 111.

The substrate 111 serves to support and protect components of the electroluminescent display device disposed thereon.

Recently, the flexible substrate 111 may be used with a flexible material having flexible characteristics such as plastic.

The flexible substrate 111 may be in a form of a film including one of the group consisting of a polyester-based polymer, a silicone-based polymer, an acrylic polymer, a polyolefin-based polymer, and a copolymer thereof.

A light blocking layer 125 may be disposed on the substrate 111.

In this case, the light blocking layer 125 may be formed of a metallic material having a light blocking function in order to block external light from flowing into semiconductor layers 124a and 124b.

The light blocking layer 125 may be formed in a single layer or multilayer structure formed of any one of opaque metals such as aluminum (Al), chromium (Cr), tungsten (W), titanium (Ti), neodymium (Nd), nickel (Ni), molybdenum (Mo) and copper (Cu), or alloys thereof.

A buffer layer 115a may be disposed over the substrate 111 on which the light blocking layer 125 is disposed.

The buffer layer 115a may be formed in a structure in which a single insulating layer or a plurality of insulating layers are stacked in order to block foreign materials including moisture, oxygen and the like, flowing from the substrate 111. That is, the buffer layer 115a may be formed of a single layer or multilayer structure of an inorganic insulating material such as silicon oxide (SiOx), silicon nitride (SiNx), or aluminum oxide (AlOx). The buffer layer 115a may be deleted according to types of the thin film transistors 120a and 120b.

The buffer layer 115a may include a contact hole exposing a portion of the light blocking layer 125.

The thin film transistors 120a and 120b may be disposed on the buffer layer 115a.

The first thin film transistor 120a in the active area may be a switching transistor.

The switching transistor is turned on by a gate pulse supplied to a gate line and transmits a data voltage that is supplied to a data line to a gate electrode of a driving transistor.

To this end, the first thin film transistor 120a may include a first gate electrode 121a, a first source electrode 122a, a first drain electrode 123a, and a first semiconductor layer 124a.

The second thin film transistor 120b in the active area may be a driving transistor, and only a part of the driving transistor is illustrated in FIG. 4 for convenience. Other sensing transistors and compensation circuits may also be included in the electroluminescent display device.

The driving transistor may transmit a current that is transmitted through a power line to the anode 131 according to a signal received from the switching transistor, and may control light emission by the current transmitted to the anode 131.

To this end, the second thin film transistor 120b may include a second gate electrode, a second source electrode, a second drain electrode 123b, and a second semiconductor layer 124b.

The semiconductor layers 124a and 124b may be formed of an oxide semiconductor. The oxide semiconductor has excellent mobility and uniformity properties. In this case, the oxide semiconductor may be formed of a quaternary metal oxide such as an indium tin gallium zinc oxide (InSnGaZnO)-based material, a ternary metal oxide such as an indium gallium zinc oxide (InGaZnO)-based material, an indium tin zinc oxide (InSnZnO)-based material, an indium aluminum zinc oxide (InAlZnO)-based material, a tin gallium zinc oxide (SnGaZnO)-based material, an aluminum gallium zinc oxide (AlGaZnO)-based material, and a tin aluminum zinc oxide (SnAlZnO)-based material, or a binary metal oxide such as an indium zinc oxide (InZnO)-based material, a tin zinc oxide (SnZnO)-based material, an aluminum zinc oxide (AlZnO)-based material, a zinc magnesium oxide (ZnMgO)-based material, a tin magnesium oxide (SnMgO)-based material, an indium oxide (InO)-based material, a tin oxide (SnO)-based material, an indium gallium oxide (InGaO)-based material, an indium magnesium oxide (InMgO)-based material, and a zinc oxide (ZnO)-based material.

The semiconductor layers 124a and 124b may include a source region including p-type or n-type impurities, a drain region, and a channel region between the source region and the drain region, and may further include a low concentration-doped region between the source region and the drain region adjacent to the channel region, but the present disclosure is not limited thereto.

The source region and the drain region are regions doped with a high concentration of impurities, and may be connected to the source electrode 122a and the drain electrodes 123a and 123b of the thin film transistors 120a and 120b, respectively.

As an impurity ion, the p-type impurity or n-type impurity may be used. The p-type impurity may be one of boron (B), aluminum (Al), gallium (Ga), and indium (In), and the n-type impurity may be one of phosphorus (P), arsenic (As), and antimony (Sb).

The channel region may be doped with the n-type impurity or p-type impurity according to an NMOS or PMOS transistor structure.

A first insulating layer 115b is a gate insulating layer composed of a single layer of silicon oxide (SiOx) or silicon nitride (SiNx), or multiple layers thereof, and may be disposed between the gate electrode 121a and the semiconductor layers 124a and 124b such that a current flowing through the semiconductor layers 124a and 124b do not flow to the gate electrode 121a. Silicon oxide is less ductile than metal, but is superior in ductility to silicon nitride and may be formed as a single layer or multiple layers according to characteristics thereof.

The gate electrode 121a may be disposed on the first insulating layer 115b.

In this case, the gate electrode 121a may be composed of a single layer or multiple layers of a conductive metal such as copper (Cu), aluminum (Al), chromium (Cr), molybdenum (Mo), gold (Au), titanium (Ti), nickel (Ni), neodymium (Nd) and the like, or alloys thereof, but the present disclosure is not limited thereto.

A second insulating layer 115c may be disposed on the gate electrode 121a as an interlayer insulating layer. The second insulating layer 115c may be formed of a single layer of silicon oxide (SiOx), silicon nitride (SiNx), or multiple layers thereof.

The source electrode 122a and the drain electrodes 123a and 123b may be disposed on the second insulating layer 115c. The source electrode 122a and the drain electrodes 123a and 123b may be composed of a single layer or multiple layers of a conductive metal such as aluminum (Al), molybdenum (Mo), chromium (Cr), gold (Au), titanium (Ti), nickel (Ni), neodymium (Nd), copper (Cu), and the like, or alloys thereof, but the present disclosure is not limited thereto.

In this case, one side of the second drain electrode 123b may be electrically connected to the second semiconductor layer 124b, and the other side of the second drain electrode 123b may be electrically connected to the light blocking layer 125.

A passivation layer 115d may be disposed on the thin film transistors 120a and 120b. The passivation layer 115d may be formed of a single layer of silicon oxide (SiOx), silicon nitride (SiNx), or multiple layers thereof.

The passivation layer 115d may serve to prevent unnecessary electrical connection between components disposed thereon and therebelow and to prevent contamination or damage from the outside, and may be omitted according to configurations and characteristics of the thin film transistors 120a and 120b and the light emitting element 130.

The thin film transistors 120a and 120b may be classified into an inverted staggered structure and a coplanar structure according to positions of components constituting the thin film transistors 120a and 120b. For example, in a thin film transistor having an inverted staggered structure, a gate electrode may be positioned on an opposite side of a source electrode and a drain electrode with respect to a semiconductor layer. For example, as shown in FIG. 4, in the thin film transistors 120a and 120b having a coplanar structure, the gate electrode 121a may be positioned on the same side of the source electrode 122a and the drain electrodes 123a and 123b.

FIG. 4 illustrates the thin film transistors 120a and 120b having the coplanar structure, but the electroluminescent display device according to the first example embodiment of the present disclosure may include a thin film transistor having the inverted staggered structure. In addition, a portion of the thin film transistors 120a and 120b may have the coplanar structure, and the other portion of the thin film transistors 120a and 120b may have the inverted staggered structure.

Planarization layers 115e and 115f may be disposed on the thin film transistors 120a and 120b to protect the thin film transistors 120a and 120b and alleviate a step caused by them and to reduce parasitic capacitance occurring between the thin film transistors 120a and 120b, the gate line and the data line, and the light emitting element 130.

The planarization layers 115e and 115f may be formed of one or more materials among acrylic resin, epoxy resin, phenolic resin, polyamides resin, polyimides resin, unsaturated polyesters resin, polyphenylene resin, polyphenylene sulfides resin, and benzocyclobutene, but the present disclosure is not limited thereto.

A first planarization layer 115e may be disposed on the thin film transistors 120a and 120b, and a second planarization layer 115f may be disposed on the first planarization layer 115e.

A buffer layer may be disposed on the first planarization layer 115e. The buffer layer may be composed of multiple layers of silicon oxide (SiOx) in order to protect components disposed on the first planarization layer 115e, and may be omitted depending on configurations and characteristics of the thin film transistors 120a and 120b and the light emitting element 130.

An intermediate electrode 126 may be electrically connected to the second thin film transistor 120b through a contact hole formed in the first planarization layer 115e.

When the intermediate electrode 126 is configured as a hydrogen adsorption layer, it may serve to adsorb external hydrogen or hydrogen in the encapsulation layer 150 to thereby block the inflow of hydrogen into the oxide thin film transistors 120a and 120b therebelow.

The intermediate electrode 126 may be formed of a metal having a hydrogen adsorption capability such as Ti or a Ti alloy of Ti/Al/Ti.

Here, Ti is a metal having a hydrogen adsorption capability and can effectively block hydrogen in structures of the encapsulation layer 150 and the oxide thin film transistors 120a and 120b.

A material constituting the intermediate electrode 126 may include Sc, V, Pd, Nb, Zr, Y, Ta, Ce, La, Sm, U, and the like, that have excellent hydrogen adsorption capability in addition to Ti.

The intermediate electrode 126 may be disposed to shield the oxide thin film transistors 120a and 120b therebelow.

A passivation layer including an inorganic insulating layer such as silicon oxide (SiOx) or silicon nitride (SiNx) may be further disposed on the first planarization layer 115e and the intermediate electrode 126. The passivation layer may serve to prevent unnecessary electrical connection between components and to prevent contamination or damage introduced from the outside, and may be omitted depending on configurations and characteristics of the thin film transistors 120a and 120b and the light emitting element 130.

Meanwhile, the light emitting element 130 including the anode 131, a light emitting structure 132, and a cathode 133 may be disposed on the second planarization layer 115f.

The anode 131 may be disposed on the second planarization layer 115f.

The anode 131 is an electrode serving to supply holes to the light emitting structure 132, and may be connected to the second thin film transistor 120b through a contact hole in the second planarization layer 115f.

In the case of a bottom emission type in which light is emitted to a lower portion where the anode 131 is disposed, the anode 131 may be formed of indium tin oxide (ITO), indium zinc oxide (IZO), or the like, which is a transparent conductive material, but the present disclosure is not limited thereto.

On the other hand, in the case of a top emission type in which light is emitted to an upper portion where the cathode 133 is disposed, the anode 131 may further include a reflective layer such that the emitted light is reflected from the anode 131 and is more smoothly emitted in a direction toward the upper portion where the cathode 133 is disposed.

That is, the anode 131 may be a two-layer structure in which a transparent conductive layer formed of a transparent conductive material and a reflective layer are sequentially stacked, or a three-layer structure in which a transparent conductive layer, a reflective layer and a transparent conductive layer are sequentially stacked. The reflective layer may be formed of silver (Ag) or an alloy including silver.

The bank 115g may be disposed on the anode 131 and the second planarization layer 115f.

In some cases, the anode 131 may be formed above the second planarization layer 115f and then the bank 115f may be formed above the anode 131 or above portions of the anode 131.

The bank 115g that is disposed on the anode 131 and the second planarization layer 115f may define sub-pixels by partitioning an area that actually emits light, that is, an emission area EA.

After a photoresist is formed on the anode 131, the bank 115g may be formed through a photolithography process.

In some cases, a bank layer may be formed above an anode layer. The bank layer may be patterned and etched to form one or more bank openings that expose a portion of the anode layer. The exposed portion of the anode layer may correspond with the anode 131. The bank layer may be deposited or formed using a variety of techniques including inkjet printing, screen printing, spin coating, physical vapor deposition (PVD), and Chemical Vapor Deposition (CVD). The bank layer may comprise an insulating layer or material, such as silicon oxide or silicon nitride. In one example, the bank layer may be initially formed above the anode 131 and a layer of photoresist may be arranged above the bank layer. An etching process may then be used to etch through portions of the bank layer to expose the anode 131. A light emitting structure, such as the light emitting structure 132 of the light emitting element 130, may include a light emitting layer that emits light and may be formed of a nitride semiconductor, such as indium gallium nitride (InGaN).

The photoresist refers to a photosensitive resin of which solubility in a developer is changed by an action of light, and a specific pattern can be obtained by exposing and developing the photoresist. The photoresist can be classified into a positive type photoresist and a negative type photoresist. In this case, the positive photoresist refers to a photoresist of which solubility in a developer for an exposed portion is increased by exposure, and when the positive photoresist is developed, a pattern in which the exposed portion is removed is obtained. The negative photoresist refers to a photoresist of which solubility in a developer for an exposed portion is lowered by exposure, and when the negative photoresist is developed, a pattern in which an unexposed portion is removed is obtained.

A fine metal mask (FMM), which is a deposition mask, may be used to form the light emitting structure 132 of the light emitting element 130.

In addition, in order to prevent damage that may be caused by contact with the deposition mask disposed on the bank 115g and to maintain a constant distance between the bank 115g and the deposition mask, the spacer 160 formed of one of benzocyclobutene, photoacrylic, and polyimide, which is a transparent organic material, may be disposed on the bank 115g.

An opening OP exposing a portion of the anode 131 may be formed by removing a portion of the bank 115g in the emission area EA.

Meanwhile, the first example embodiment of the present disclosure is characterized in that the plurality of hydrogen adsorption layers 165 and 167 are disposed on the banks 115g between the plurality of sub-pixels. In this case, the first hydrogen adsorption layer 165 may be disposed under the spacer 160, while the second hydrogen adsorption layer 167 may not be disposed under the spacer 160.

As described above, in the first example embodiment of the present disclosure, the hydrogen adsorption layers 165 and 167 are formed on upper portions of the banks 115g other than the area where the anode 131 is positioned, that is, the emission area EA, to thereby block an inflow of hydrogen H into the oxide thin film transistors 120a and 120b (see arrow in FIG. 4), so that characteristics and reliability of the oxide thin film transistors 120a and 120b can be improved.

The hydrogen adsorption layers 165 and 167 may be formed of a metal having a hydrogen adsorption capability such as Ti or a Ti alloy of Ti/Al/Ti.

A material constituting the hydrogen adsorption layers 165 and 167 may include Sc, V, Pd, Nb, Zr, Y, Ta, Ce, La, Sm, U, and the like, that have excellent hydrogen adsorption capability in addition to Ti. For reference, a hydrogen solubility of TiH is superior to those of AlH, NiH, AgH, CuH and ZnH.

Looking at a metal hydride, for example, hydride of Ti is TiH_{2.00}, which means that two hydrogens H can be stored in one Ti, and it can be seen that hydrogen adsorption capability thereof is a million times superior than AlH<_{2.5x10-8}. That is, it can be seen that Ti has a hydrogen adsorption capacity 100,000 times superior than Cu and a million times superior than Al.

It can be seen that hydrides of Sc, V, Pd, Nb, Zr, Y, Ta, Ce, La, Sm, and U are ScH>_{1.86}, VH_{1.00}, PdH_{0.724}, NbH_{1.1}, ZrH>_{1.70}, YH>_{2.85}, TaH_{0.79}, CeH>_{2.5}, LaH>_{2.03}, SmH_{3.00}, UH>₃.₀₀, respectively.

The hydrogen adsorption layers 165 and 167 may be formed in non-emission areas NEA other than the emission area EA, and due to the forming of the hydrogen adsorption layers 165 and 167 of Ti, a reflective area increases, so that an ambient contrast ratio (ACR) may be advantageously increased.

In order to improve an interface of Ti with the hydrogen adsorption layers 165 and 167, the spacer 160 may be formed wider than an existing area thereof.

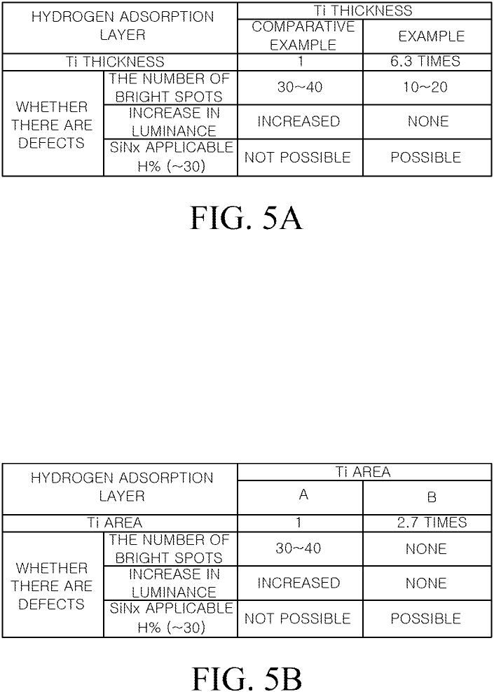

FIGS. 5A and 5B are tables respectively showing reliability results of a display panel according to a thickness and an area of a hydrogen adsorption layer.

FIG. 5A shows the reliability results of the display panel according to the thickness of the hydrogen adsorption layer, and FIG. 5B shows the reliability results of the display panel according to the area of the hydrogen adsorption layer.

FIG. 5A shows reliability results of a display panel according to Example in which a hydrogen adsorption layer has a Ti thickness 6.3 times greater than that of Comparative Example by comparing the Example and the Comparative Example, and FIG. 5b shows reliability results of a display panel according to Example in which a hydrogen adsorption layer has a Ti area 2.7 times greater than that of Comparative Example by comparing the Example and the Comparative Example.

Referring to FIG. 5A, in the case of the Comparative Example, it can be seen that silicon nitride containing about 30% hydrogen cannot be used in an encapsulation layer due to an increase in luminance and 30 to 40 bright spots.

On the other hand, in the case of the Example using the hydrogen adsorption layer having a Ti thickness 6.3 times greater than that of the Comparative Example, it can be seen that silicon nitride containing about 30% hydrogen can be used in an encapsulation layer since the number of the bright points is reduced to 10 to 20 and there is no increase in luminance.

Referring to FIG. 5B, in the case of the Example using the hydrogen adsorption layer having a Ti area 2.7 times greater than that of the Comparative Example, it can be seen that silicon nitride containing about 30% hydrogen can be used in an encapsulation layer because there is no bright spot and no increase in luminance.

Accordingly, it can be seen that it is possible to use the hydrogen adsorption layer in a wide range.

As such, it can be seen that as a layer having a high Ti content is formed, defects caused by hydrogen are reduced.

Therefore, it is possible to improve a yield of an electroluminescent display device to which the oxide thin film transistor is applied. In addition, it is possible to implement a low-power product through low-frequency (low Hz) driving, and a TFE encapsulation structure can be applied to the top emission type regardless of a hydrogen content, so that a degree of technical freedom can increase.

Referring back to FIG. 4, the light emitting structure 132 may be disposed between the anode 131 and the cathode 133.

The light emitting structure 132 which serves to emit light, may include at least one layer of a hole injection layer (HIL), a hole transport layer (HTL), a light emitting layer, an electron transport layer (ETL), and an electron injection layer (EIL), and some of the components may be omitted according to a structure or characteristics of the electroluminescent display device. Here, as the light emitting layer, an electroluminescent layer and an inorganic light emitting layer may also be applied.

The hole injection layer is disposed on the anode 131 and serves to facilitate hole injection.

The hole transport layer is disposed on the hole injection layer and serves to smoothly transfer holes to the light emitting layer.

The light emitting layer is disposed on the hole transport layer, and may include a material capable of emitting light of a specific color to thereby emit light of a specific color. In addition, a light emitting material may be formed using a phosphorescent material or a fluorescent material.

The electron injection layer may be further disposed on the electron transport layer. The electron injection layer is an organic layer that facilitates injection of electrons from the cathode 133, and may be omitted according to the structure and characteristics of the electroluminescent display device.

Meanwhile, by further disposing an electron blocking layer or a hole blocking layer for blocking a flow of holes or electrons at a position adjacent to the light emitting layer, it is possible to prevent a phenomenon in which the electrons move from the light emitting layer when injected into the light emitting layer and pass through the hole transport layer adjacent thereto or a phenomenon in which the holes move from the light emitting layer when injected into the light emitting layer and pass through the electron transport layer adjacent thereto, so that luminous efficiency can be improved.

The cathode 133 is disposed on the light emitting structure 132 and serves to supply electrons to the light emitting structure 132. In the bottom emission type, since the cathode 133 needs to supply electrons, it may be formed of a metallic material such as magnesium, silver-magnesium, which is a conductive material having a low work function, but is not limited thereto.

On the other hand, in the case of the top emission type, the cathode 133 may be formed of a transparent conductive oxide, such as indium tin oxide (ITO), indium zinc oxide (IZO), indium tin zinc oxide (ITZO), zinc oxide (ZnO) and tin oxide (TO).

The encapsulation layer 150 may be disposed on the cathode 133.

Specifically describing the encapsulation layer 150, a capping layer is formed on an upper surface of the substrate 111 on which the light emitting element 130 is formed, and a primary protective layer 150a, an organic layer 150b, and a secondary protective layer 150c are sequentially formed to constitute the encapsulation layer 150 serving as an encapsulation means. However, the number of inorganic layers and organic layers constituting the encapsulation layer 150 is not limited thereto.

In the case of the primary protective layer 150a, since it is formed of an inorganic insulating layer, stack coverage thereof is not good due to a lower step. However, since the organic layer 150b serves to perform planarization, the secondary protective layer 150c is not affected by a step due to a lower layer. In addition, since a thickness of the organic layer 150b formed of a polymer is sufficiently thick, cracks caused by foreign materials can be compensated.

On a front surface of the substrate 111 including the secondary protective layer 150c, a multilayered protective film may be positioned to face it for encapsulation, and an adhesive which is transparent and has adhesive properties may be interposed between the encapsulation layer 150 and the protective film.

A polarizing plate for preventing reflection of light incident from the outside may be attached onto the protective film, but is not limited thereto.

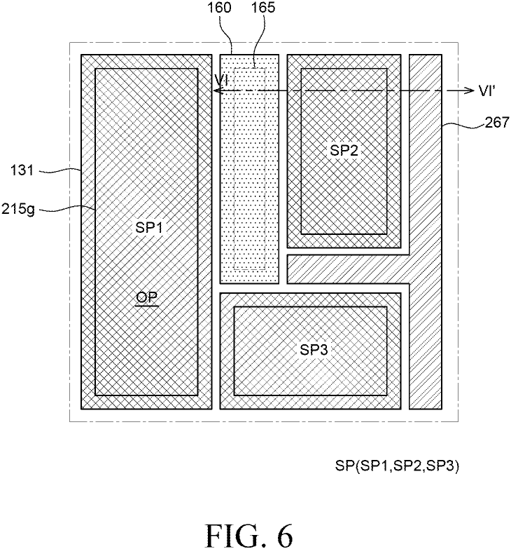

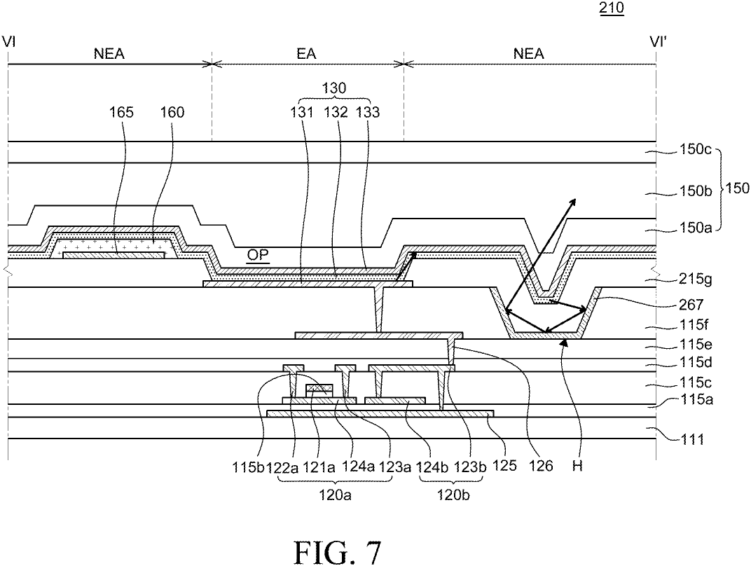

Meanwhile, the hydrogen adsorption layer of the present disclosure may be formed in a “U″-shape in the bank to improve reflection characteristics, which will be described with reference to FIGS. 6 and 7.

FIG. 6 is a plan view illustrating a pixel structure according to a second example embodiment of the present disclosure.

FIG. 7 is a cross-sectional view taken along VI-VI′ of FIG. 6.

The second example embodiment of FIGS. 6 and 7 is different from the first example embodiment of FIGS. 3 and 4, which is described above, only in terms of configurations of banks 215g and a second hydrogen adsorption layer 267 and other configurations thereof are substantially the same, and thus, a duplicate description will be omitted. The same reference numerals are used for the same components.

In FIG. 6, only the anode 131 and the banks 215g are illustrated among components of the light emitting element 130 for convenience of explanation. The bank 215g may be disposed in a remaining area other than an area exposed by an opening OP.

Referring to FIGS. 6 and 7, an electroluminescent display device according to the second example embodiment of the present disclosure may include a display panel 210 that is divided into an active area and a non-active area.

A plurality of sub-pixels SP constituting a plurality of pixels and circuits for driving the plurality of sub-pixels SP may be disposed in the active area.

The plurality of spacers 160 may be disposed between the plurality of sub-pixels SP.

The second example embodiment of the present disclosure is characterized in that a plurality of the hydrogen adsorption layers 165 and 267 are disposed between the plurality of sub-pixels SP.

In this case, for example, the hydrogen adsorption layers 165 and 267 may include a first hydrogen adsorption layer 165 disposed between the first sub-pixel SP1 and the second sub-pixel SP2 and a second hydrogen adsorption layer 267 disposed between the second sub-pixel SP2/the third sub-pixel SP3 and the first sub-pixel SP1.

The first hydrogen adsorption layer 165 may be disposed between the first sub-pixel SP1 and the second sub-pixel SP2 in the column direction, and the second hydrogen adsorption layer 267 may be disposed between the second sub-pixel SP2/the third sub-pixel SP3 and the first sub-pixel SP1 in the column direction, while a portion of the second hydrogen adsorption layer 267 may extend between the second sub-pixel SP2 and the third sub-pixel SP3 in the row direction. However, the present disclosure is not limited thereto.

The first hydrogen adsorption layer 165 may be disposed under the spacer 160.

As described above, in the second example embodiment of the present disclosure, the first hydrogen adsorption layer 165 is formed on the bank 215g except for an area where the anode 131 is positioned, and the second hydrogen adsorption layer 267 is formed within the second planarization layer 115f to thereby block an inflow of hydrogen into the oxide thin film transistors 120a and 120b, so that characteristics and reliability of the oxide thin film transistors 120a and 120b can be improved.

The planarization layers 115e and 115f may be disposed on the thin film transistors 120a and 120b.

As described above, the intermediate electrode 126 may be formed on the first planarization layer 115e.

When the intermediate electrode 126 is configured as a hydrogen adsorption layer, the intermediate electrode 126 may be formed of a metal having a hydrogen adsorption capability such as Ti or a Ti alloy of Ti/Al/Ti.

A material constituting the intermediate electrode 126 may include Sc, V, Pd, Nb, Zr, Y, Ta, Ce, La, Sm, U, and the like, that have excellent hydrogen adsorption capability in addition to Ti.

The intermediate electrode 126 may be disposed to shield the oxide thin film transistors 120a and 120b therebelow.

Meanwhile, the second example embodiment of the present disclosure is characterized in that a portion of the second planarization layer 115f between the plurality of sub-pixels SP is removed to thereby form a predetermined groove H. The groove H may be formed in the non-emission area NEA in which the anode 131 and the intermediate electrode 126 are not disposed.

The groove H has a “U″-shape, and may have a taper in which a side surface thereof is inclined outwardly in an upward direction.

In addition, the second hydrogen adsorption layer 267 may be disposed on an inner surface of the groove H. In this case, the second hydrogen adsorption layer 267 may have a taper in which a side surface thereof is inclined outwardly in the upward direction along the shape of the groove H.

The second hydrogen adsorption layer 267 may be formed of a metal having a hydrogen adsorption capability such as Ti or a Ti alloy of Ti/Al/Ti.

A material constituting the second hydrogen adsorption layer 267 may include Sc, V, Pd, Nb, Zr, Y, Ta, Ce, La, Sm, U, and the like, that have excellent hydrogen adsorption capability in addition to Ti.

As the second hydrogen adsorption layer 267 has a “U″-shape and has a taper in which the side surface thereof is inclined outwardly in the upward direction as described above, light emitted between the cathode 133 and the anode 131, in particular, a direction of laterally leaking light may be converted into the upward direction (refer to an arrow of FIG. 7), whereby light extraction efficiency may be improved.

In some cases, it is better as a thickness of the second hydrogen adsorption layer 267 increases; for example, the second hydrogen adsorption layer 267 may have a thickness of at least 300 Å.

Meanwhile, the light emitting element 130 including the anode 131, the light emitting structure 132, and the cathode 133 may be disposed on the second planarization layer 115f.

In this case, the bank 215g may be disposed on the anode 131 and the second planarization layer 115f.

The bank 215g may also be formed on the second hydrogen adsorption layer 267 to fill an inside of the groove H.

The first hydrogen adsorption layer 165 may be formed on the bank 215g in the non-emission area NEA. In addition, the spacer 160 that is formed of one of photoacrylic and benzocyclobutene may be formed on the first hydrogen adsorption layer 165 to cover the first hydrogen adsorption layer 165.

The first hydrogen adsorption layer 165 may be formed of a metal having a hydrogen adsorption capability such as Ti or a Ti alloy of Ti/Al/Ti.

A material constituting the first hydrogen adsorption layer 165 may include Sc, V, Pd, Nb, Zr, Y, Ta, Ce, La, Sm, U, and the like, that have excellent hydrogen adsorption capability in addition to Ti.

It is better as a thickness of the first hydrogen adsorption layer 165 increases; in some cases, the first hydrogen adsorption layer 165 may have a thickness of at least 300 Å.

As described above, in the second example embodiment of the present disclosure, as the intermediate electrode 126 and the first and second hydrogen adsorption layers 165 and 267 are formed in the non-emission areas NEA, an area of Ti constituting the intermediate electrode 126 and the first and second hydrogen adsorption layers 165 and 267 may be substantially increased, so that a hydrogen trapping effect can be maximized.

As described above, in the second example embodiment of the present disclosure, the first hydrogen adsorption layer 165 is formed on the bank 215g in the non-emission area NEA excluding the area where the anode 131 is positioned, that is, the emission area EA, and at the same time, the second hydrogen adsorption layer 267 is formed within the second planarization layer 115f to thereby block the inflow of hydrogen into the oxide thin film transistors 120a and 120b, so that characteristics and reliability of the oxide thin film transistors 120a and 120b can be improved.

The first and second hydrogen adsorption layers 165 and 267 may be formed in the non-emission areas NEA other than the emission area EA, and due to the forming of the hydrogen adsorption layers 165 and 267 of Ti, a reflective area increases, so that an ambient contrast ratio (ACR) may be advantageously increased.

In particular, in the case of the second example embodiment, as the second hydrogen adsorption layer 267 has a “U″-shape and has a taper in which the side surface thereof is inclined outwardly in the upward direction, a direction of light leaking between the cathode 133 and the anode 131 may be converted into the upward direction, whereby light extraction efficiency may be improved.

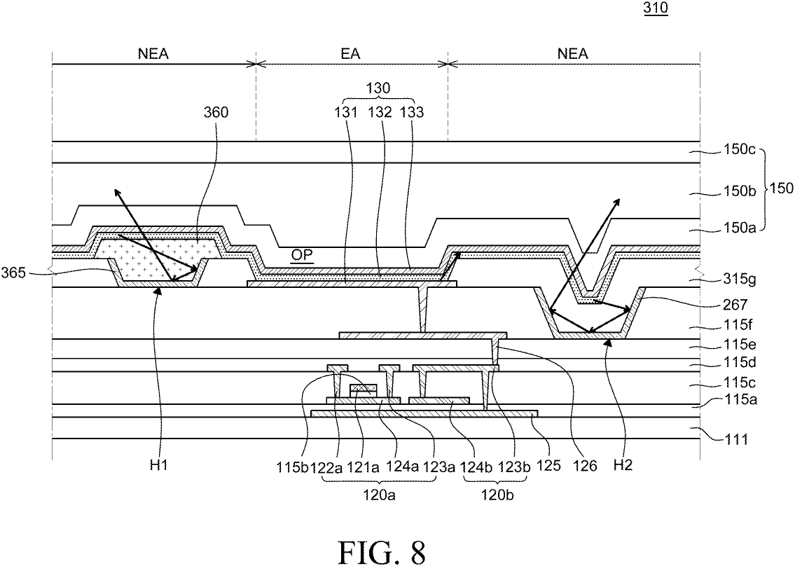

Meanwhile, in the present disclosure, the first hydrogen adsorption layer may be formed in a “U″-shape, which will be described with reference to FIG. 8.

FIG. 8 is a cross-sectional view of an electroluminescent display device according to a third example embodiment of the present disclosure.

The third example embodiment of FIG. 8 is different from the second example embodiment of FIGS. 6 and 7, which is described above, only in terms of configurations of a bank 315g and a first hydrogen adsorption layer 365 and other configurations thereof are substantially the same, and thus, a duplicate description will be omitted. The same reference numerals are used for the same components.

Referring to FIG. 8, the electroluminescent display device according to the third example embodiment of the present disclosure may include a display panel 310 that is divided into an active area and a non-active area.

A plurality of spacers 360 may be disposed between a plurality of sub-pixels.

The third example embodiment of the present disclosure is characterized in that a plurality of the hydrogen adsorption layers 365 and 267 are disposed between the plurality of sub-pixels.

That is, the third example embodiment of the present disclosure is characterized in that the first hydrogen adsorption layer 365 is formed in the bank 315g in the non-emission area NEA other than the emission area EA where the anode 131 is positioned, and the second hydrogen adsorption layer 267 is formed within the planarization layer 115f.

In addition, it is characterized in that the intermediate electrode 126 composed of a hydrogen adsorption layer is formed on the first planarization layer 115e to shield the oxide thin film transistors 120a and 120b.

Accordingly, it is possible to improve characteristics and reliability of the oxide thin film transistors 120a and 120b by blocking the inflow of hydrogen into the oxide thin film transistors 120a and 120b.

In particular, the first hydrogen adsorption layer 365 may be disposed under the spacer 360.

When the intermediate electrode 126 is configured as a hydrogen adsorption layer, the intermediate electrode 126 may be formed of a metal having a hydrogen adsorption capability such as Ti or a Ti alloy of Ti/Al/Ti.

In addition, the first and second hydrogen adsorption layers 365 and 267 may be formed of a metal having a hydrogen adsorption capability such as Ti or a Ti alloy of Ti/Al/Ti.

Materials constituting the first and second hydrogen adsorption layers 365 and 267 and the intermediate electrode 126 may include Sc, V, Pd, Nb, Zr, Y, Ta, Ce, La, Sm, U, and the like, that have excellent hydrogen adsorption capability in addition to Ti.

As described above, the intermediate electrode 126 may be disposed to shield the oxide thin film transistors 120a and 120b therebelow.

In addition, it is characterized in that a partial region of the bank 315g between the plurality of sub-pixels is removed to thereby form a first groove H1 and a partial region of the second planarization layer 115f between the plurality of sub-pixels is removed to thereby form a second groove H2. The first and second grooves H1 and H2 may be formed in the non-emission areas NEA in which the anode 131 and the intermediate electrode 126 are not disposed.

The first and second grooves H1 and H2 have a “U″-shape, and may have a taper in which a side surface thereof is inclined outwardly in an upward direction.

In addition, the first and second hydrogen adsorption layers 365 and 267 may be disposed on inner surfaces of the first and second grooves H1 and H2, respectively. In this case, the first and second hydrogen adsorption layers 365 and 267 may have tapers in which the side surfaces thereof are inclined outwardly in the upward direction along the shapes of the first and second grooves H1 and H2.

As the first and second hydrogen adsorption layers 365 and 267 have a “U″-shape and have a taper in which the side surface thereof is inclined outwardly in the upward direction as described above, light emitted between the cathode 133 and the anode 131, in particular, a direction of laterally leaking light may be converted into the upward direction (refer to arrows of FIG. 8), whereby light extraction efficiency may be further improved.

It is better as a thickness of the first and second hydrogen adsorption layers 365 and 267 increases; in some cases, the first and second hydrogen adsorption layers 365 and 267 may have a thickness of at least 300 Å.

The bank 315g may be disposed on the anode 131 and the second planarization layer 115f.

The bank 315g may also be formed on the second hydrogen adsorption layer 267 to fill an inside of the second groove H2.

In addition, the spacer 360 may be disposed on the bank 315g.

The spacer 360 formed of one of photoacrylic and benzocyclobutene may also be formed on the first hydrogen adsorption layer 365 to fill the inside of the first groove H1.

As described above, in the third example embodiment of the present disclosure, as the intermediate electrode 126 and the first and second hydrogen adsorption layers 365 and 267 are formed over an entirety of the display panel 310, an area of Ti constituting the intermediate electrode 126 and the first and second hydrogen adsorption layers 365 and 267 may be substantially increased, so that a hydrogen trapping effect can be maximized.

The first and second hydrogen adsorption layers 365 and 267 may be formed in the non-emission areas NEA other than the emission area EA, and due to the forming of the hydrogen adsorption layers 365 and 267 of Ti, a reflective area increases, so that an ambient contrast ratio (ACR) may be advantageously increased.

In particular, in the case of the third example embodiment, as the first and second hydrogen adsorption layers 365 and 267 have a “U″-shape and have a taper in which the side surface thereof is inclined outwardly in the upward direction, a direction of light leaking between the cathode 133 and the anode 131 may be converted into the upward direction, whereby light extraction efficiency may be further improved.

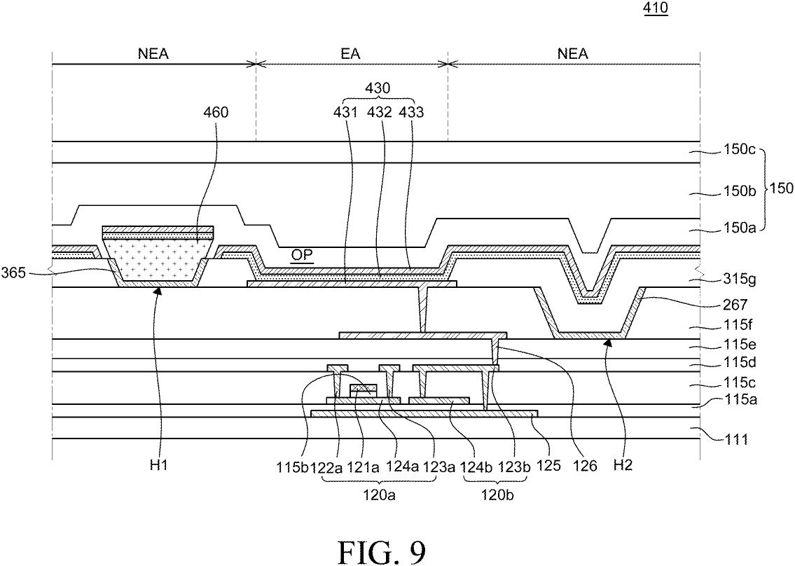

Meanwhile, a spacer of the present disclosure may have a reversely tapered shape, which will be described with reference to FIG. 9.

FIG. 9 is a cross-sectional view of an electroluminescent display device according to a fourth example embodiment of the present disclosure.

The fourth example embodiment of the present disclosure shown in FIG. 9 is different from the third example embodiment of FIG. 8, which is described above, only in terms of a configuration of a spacer 460 and other configurations thereof are substantially the same, and thus, a duplicate description will be omitted. The same reference numerals are used for the same components.

Referring to FIG. 9, the electroluminescent display device according to the fourth example embodiment of the present disclosure may include a display panel 410 that is divided into an active area and a non-active area.

A plurality of spacers 460 may be disposed between the plurality of sub-pixels.

The spacer 460 according to the fourth example embodiment of the present disclosure is characterized by having a reversely tapered shape in which an upper surface is wider than a lower surface thereof. Accordingly, a portion of a light emitting structure 432 and a cathode 433 that are formed on the spacer 460 may be disconnected (discontinued) between the sub-pixels, and a lateral leakage current generated in a multi-stack structure may be minimized.

Specifically, in order to improve quality and productivity of an electroluminescent display device, various light emitting element structures have been proposed to improve efficiency, lifespan, and power consumption of the light emitting element.

Accordingly, as well as a light emitting element to which one stack, that is, one light emitting structure is applied, light emitting elements having a tandem structure in which a plurality of stacks, that is, stacking of a plurality of light emitting structures is used to realize improved efficiency and lifespan characteristics, have been suggested.

In such a light emitting element of the tandem structure, that is, a two-stack structure using stacking of a first light emitting structure and a second light emitting structure, an emission area where light is emitted by recombination of electrons and holes is positioned in each of the first light emitting structure and the second light emitting structure, and light emitted from a first emission layer of the first emission structure and light emitted from a second emission layer of the second emission structure may respectively cause constructive interference, so that the light emitting element of the two-stack structure may provide high luminance as compared to a light emitting element of a single stack structure.

In addition, a distance between a plurality of sub-pixels constituting one pixel in a light emitting element decrease as a light emitting display device is higher in resolution. Auxiliary organic layers such as a hole injection layer EIL, a hole transport layer HTL, a charge generation layer CGL, an electron injection layer EIL, an electron transport layer ETL, and the like, except for an emission layer are deposited to correspond to all of the plurality of sub-pixels using a common mask and are formed as common layers, and the emission layers in the plurality of sub-pixels that respectively generate light of different wavelength may be individually deposited and formed to correspond to the respective sub-pixels with the use of a fine mask.

In the case of the light emitting element as described above, when a voltage is applied between an anode and a cathode, a lateral leakage current is generated in a lateral direction of the light emitting element through the common layer formed in the light emitting element. Accordingly, a color mixing defect occurs as not only sub-pixels where light emission is required, but also sub-pixels where light emission is unwanted, which are located adjacent thereto emit light.

Such color mixing defect may be more severe in the light emitting element of the two-stack structure using the staking of the first light emitting structure and the second light emitting structure which uses constructive interference of light, compared to the light emitting element of the single stack structure.

Accordingly, the fourth example embodiment of the present disclosure is characterized in that a leakage current due to a light emitting structure 432 between adjacent sub-pixels is minimized by applying the spacer 460 having a reversely tapered shape.

In addition, the fourth example embodiment of the present disclosure is characterized in that the plurality of hydrogen adsorption layers 365 and 267 are disposed between the plurality of sub-pixels.

That is, the fourth example embodiment of the present disclosure is characterized in that the first hydrogen adsorption layer 365 is formed in the bank 315g in the non-emission area NEA other than the emission area EA where an anode 431 is positioned, and the second hydrogen adsorption layer 267 is formed within the planarization layer 115f.

In addition, the intermediate electrode 126 composed of a hydrogen adsorption layer is formed on the first planarization layer 115e to shield the oxide thin film transistors 120a and 120b.

Accordingly, it is possible to improve characteristics and reliability of the oxide thin film transistors 120a and 120b by blocking the inflow of hydrogen into the oxide thin film transistors 120a and 120b.

In particular, the first hydrogen adsorption layer 365 may be disposed under the spacer 460.

When the intermediate electrode 126 is configured as a hydrogen adsorption layer, the intermediate electrode 126 may be formed of a metal having a hydrogen adsorption capability such as Ti or a Ti alloy of Ti/Al/Ti.

In addition, the first and second hydrogen adsorption layers 365 and 267 may be formed of a metal having a hydrogen adsorption capability such as Ti or a Ti alloy of Ti/Al/Ti.

Materials constituting the first and second hydrogen adsorption layers 365 and 267 and the intermediate electrode 126 may include Sc, V, Pd, Nb, Zr, Y, Ta, Ce, La, Sm, U, and the like, that have excellent hydrogen adsorption capability in addition to Ti.

As described above, the intermediate electrode 126 may be disposed to shield the oxide thin film transistors 120a and 120b therebelow.

In addition, it is characterized in that a partial region of the bank 315g between the plurality of sub-pixels is removed to thereby form the first groove H1, and a partial region of the second planarization layer 115f between the plurality of sub-pixels is removed to thereby form the second groove H2. The first and second grooves H1 and H2 may be formed in the non-emission areas NEA in which the anode 431 and the intermediate electrode 126 are not disposed.

The first and second grooves H1 and H2 may have a “U″-shape, and may have a taper in which the side surface thereof is inclined outwardly in the upward direction.

In addition, the first and second hydrogen adsorption layers 365 and 267 may be disposed on inner surfaces of the first and second grooves H1 and H2, respectively. In this case, the first and second hydrogen adsorption layers 365 and 267 may have tapers in which the side surfaces thereof are inclined outwardly in the upward direction along the shapes of the first and second grooves H1 and H2.

As the first and second hydrogen adsorption layers 365 and 267 have a “U″-shape and have a taper in which the side surface thereof is inclined outwardly in the upward direction as described above, light emitted between the cathode 433 and the anode 431, in particular, a direction of laterally leaking light may be converted into the upward direction, whereby light extraction efficiency may be further improved.

It is better as a thickness of the first and second hydrogen adsorption layers 365 and 267 increases. In some cases, the first and second hydrogen adsorption layers 365 and 267 may have a thickness of at least 300 Å.

As described above, the bank 315g may also be formed on the second hydrogen adsorption layer 267 to fill the inside of the second groove H2.

In addition, the spacer 460 having a reversely tapered shape may also be formed on the first hydrogen adsorption layer 365 to fill the inside of the first groove H1.

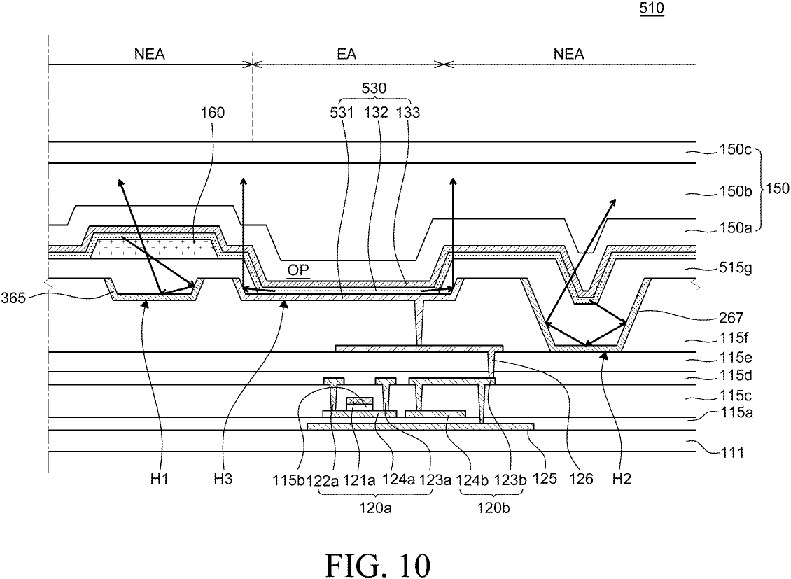

FIG. 10 is a cross-sectional view of an electroluminescent display device according to a fifth example embodiment of the present disclosure.

The fifth example embodiment of FIG. 10 is different from the second to fourth example embodiments described above, only in terms of configurations of banks 515g, an anode 531, and a second planarization layer 115f and other configurations thereof are substantially the same, and thus, a duplicate description will be omitted. The same reference numerals are used for the same components.

Referring to FIG. 10, the electroluminescent display device according to the fifth example embodiment of the present disclosure may include a display panel 510 that is divided into an active area and a non-active area.

It is characterized in that partial regions of the second planarization layer 115f between the plurality of sub-pixels are removed to thereby form first and second grooves H1 and H2, and a partial region of the second planarization layer 115f in the sub-pixel is removed to thereby form a third groove H3. The first and second grooves H1 and H2 may be formed in non-emission areas NEA in which the anode 531 and the intermediate electrode 126 are not disposed, and the third groove H3 may be formed in an emission area EA in which the anode 531 and the intermediate electrode 126 are disposed, that is, formed in the emission area EA to overlap the anode 531 and the intermediate electrode 126.

The first to third grooves H1, H2, and H3 may have a “U″-shape, and may have a taper in which a side surface thereof is inclined outwardly in an upward direction.

In addition, the first and second hydrogen adsorption layers 365 and 267 may be disposed on inner surfaces of the first and second grooves H1 and H2, respectively, and the anode 531 may be disposed on an inner surface of the third groove H3. At this time, the first and second hydrogen adsorption layers 365 and 267 and the anode 531 may have tapers in which the side surfaces thereof are inclined outwardly in the upward direction along the shapes of the first to third grooves H1, H2, and H3. Although the fifth example embodiment of the present disclosure illustrates that the first and second grooves H1 and H2 are formed and the first and second hydrogen adsorption layers 365 and 267 are respectively disposed on the inner surfaces thereof, the first and second hydrogen adsorption layers 365 and 267 may be disposed on the second planarization layer 115f in non-opening portions of the banks 515g without forming the first and second grooves H1 and H2. In this case, at least one hydrogen adsorption layer may be formed simultaneously with the anode 531.

As the first and second hydrogen adsorption layers 365 and 267 and the anode 531 have a “U″-shape and have a taper in which the side surface thereof is inclined outwardly in the upward direction as described above, light emitted between the cathode 133 and the anode 531, in particular, a direction of laterally leaking light may be converted into the upward direction (refer to arrows of FIG. 10), thereby inducing light extraction to the non-emission areas NEA, so that light extraction efficiency may be further improved.

It is better as a thickness of the first and second hydrogen adsorption layers 365 and 267 increases. In some cases, the first and second hydrogen adsorption layers 365 and 267 may have a thickness of at least 300 Å.

The banks 515g may be formed on the first and second hydrogen adsorption layers 365 and 267 to fill insides of the first and second grooves H1 and H2. However, in the third groove H3 overlapping the emission area EA, a portion of the bank 515g may be removed to thereby form an opening OP exposing a portion of the anode 531.

In other words, while the first to third grooves H1, H2, and H3 are formed in the non-emission areas NEA other than the emission area EA, that is, in the non-opening portions of the banks 515g excluding the opening OP, a portion of the third groove H3 may be exposed through the opening OP.

As described above, in the fifth example embodiment of the present disclosure, the first and second hydrogen adsorption layers 365 and 267 are formed in the first and second grooves H1 and H2 of the second planarization layer 115f in the non-emission area NEAs to thereby block the inflow of hydrogen into the oxide thin film transistors 120a and 120b, so that characteristics and reliability of the oxide thin film transistors 120a and 120b may be improved. In particular, since the second groove H2 has a greater depth than that of the first groove H1, the second hydrogen adsorption layer 267 may be disposed to have a deeper and greater area according to the depth of the second groove H2, so that it is possible to further effectively block the inflow of hydrogen into the oxide thin film transistors 120a and 120b.

In addition, since the first and second hydrogen adsorption layers 165 and 267 of Ti are formed in the non-emission areas NEA other than the emission area EA, a reflective area increases, so that an ambient contrast ratio (ACR) may be advantageously increased. In addition, since the anode 531 is formed along the shape of the third groove H3 of the second planarization layer 115f including the emission area EA, the reflective area on the inclined side surface increases, so that light extraction efficiency may be further improved.

Although not shown, as compared to the above-described first and second example embodiments, other configurations of the fifth example embodiment of FIG. 10 may be substantially identically applied except for the third groove H3. That is, in the non-opening portion of the bank 515g, the first hydrogen adsorption layer 165 or the second hydrogen adsorption layers 167 and 267 of the first or second example embodiment may be formed, and in the opening OP of the bank 515g in which the third groove H3 is positioned, the anode 531 of the fifth example embodiment may be formed. At least one hydrogen adsorption layer may be formed simultaneously with the anode 531.

In some cases, the example embodiments of the present disclosure can also be described as follows: According to an aspect of the present disclosure, there is provided an electroluminescent display device. The electroluminescent display device includes a substrate divided into a plurality of sub-pixels having an emission area and a non-emission area, an oxide thin film transistor disposed on the substrate, a planarization layer disposed on the oxide thin film transistor, an anode disposed on the planarization layer in the emission area, a bank disposed on the anode and the planarization layer and having an opening exposing a portion of the anode, a first hydrogen adsorption layer disposed on the planarization layer in the non-emission area; a spacer disposed on the first hydrogen adsorption layer and a light emitting structure and a cathode disposed on the exposed anode, the bank, and the spacer.

The electroluminescent display device may further include an encapsulation layer disposed on the cathode.

The spacer may be disposed to cover the first hydrogen adsorption layer.

The first hydrogen adsorption layer may be disposed on the bank.

The bank under the spacer may be removed to thereby form a first groove, and the first hydrogen adsorption layer may be disposed on an inner surface of the first groove.

The spacer may be disposed on the first hydrogen adsorption layer to fill an inside of the first groove.

The spacer may have a reversely tapered shape in which an upper surface is wider than a lower surface thereof.

A portion of the light emitting structure and the cathode disposed on the spacer may be disconnected (discontinued) between the sub-pixels.

The electroluminescent display device may further include a second hydrogen adsorption layer disposed on the bank in the non-emission area other than an area in which the first hydrogen adsorption layer and the spacer are disposed.

The first hydrogen adsorption layer and the second hydrogen adsorption layer may be made of Ti or a Ti alloy of Ti/Al/Ti.

The first hydrogen adsorption layer and the second hydrogen adsorption layer may be made of any one metal of Sc, V, Pd, Nb, Zr, Y, Ta, Ce, La, Sm, and U.

The planarization layer may include a first planarization layer disposed on the oxide thin film transistor; and a second planarization layer disposed on the first planarization layer.

The electroluminescent display device may further include an intermediate electrode disposed on the first planarization layer and electrically connecting the anode and the oxide thin film transistor.

The intermediate electrode may be made of Ti or a Ti alloy of Ti/Al/Ti.

The intermediate electrode may be made of any one metal of Sc, V, Pd, Nb, Zr, Y, Ta, Ce, La, Sm, and U.

The second planarization layer in the non-emission area may be removed to thereby form a second groove, and the electroluminescent display device may further include a second hydrogen adsorption layer disposed on an inner surface of the second groove.

The second groove may be configured by removing the second planarization layer in the non-emission area other than an area in which the anode, the first hydrogen adsorption layer, and the intermediate electrode are disposed.

The first groove and the second groove may have a “U″-shape and have a taper in which a side surface thereof is inclined outwardly in an upward direction.

The first hydrogen adsorption layer and the second hydrogen adsorption layer may have a “U″-shape, and have a taper in which the side surface thereof is inclined outwardly in the upward direction.

The bank may be disposed on the second hydrogen adsorption layer to fill an inside of the second groove.

The bank may further include a non-opening portion covering a portion of the anode and the planarization layer, and the first hydrogen adsorption layer may be disposed in the non-opening portion of the bank.

The electroluminescent display device may further include a second hydrogen adsorption layer configured to have a greater area or a greater depth than that of the first hydrogen adsorption layer.

The electroluminescent display device may further include a third groove provided by removing a partial region of the second planarization layer of the sub-pixel, and the anode may be disposed on an inner surface of the third groove.

The third groove may have a “U″-shape and may have a taper in which a side surface thereof is inclined outwardly in an upward direction.

Although the example embodiments of the present disclosure have been described in detail with reference to the accompanying drawings, the present disclosure is not limited thereto and may be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An electroluminescent display device, comprising:
a substrate having a plurality of sub-pixels thereon, the substrate having an emission area and a non-emission area;
an oxide thin film transistor disposed on the substrate;
a planarization layer disposed on the oxide thin film transistor;
an anode disposed on the planarization layer in the emission area;
a bank disposed on the anode and the planarization layer and having an opening exposing a portion of the anode;
a first hydrogen adsorption layer disposed on the planarization layer in the non-emission area;
a spacer disposed on the first hydrogen adsorption layer; and
a light emitting structure and a cathode disposed on the exposed anode, the bank, and the spacer.

2. The electroluminescent display device of claim 1, further comprising an encapsulation layer disposed on the cathode.

3. The electroluminescent display device of claim 1, wherein the spacer is disposed to cover the first hydrogen adsorption layer.

4. The electroluminescent display device of claim 3, wherein the first hydrogen adsorption layer is disposed on the bank.

5. The electroluminescent display device of claim 1, wherein the bank under the spacer is removed to thereby form a first groove,
wherein the first hydrogen adsorption layer is disposed on an inner surface of the first groove.

6. The electroluminescent display device of claim 5, wherein the spacer is disposed on the first hydrogen adsorption layer to fill an inside of the first groove.

7. The electroluminescent display device of claim 5, wherein the spacer has a reversely tapered shape in which an upper surface is wider than a lower surface thereof.

8. The electroluminescent display device of claim 7, wherein a portion of the light emitting structure and the cathode disposed on the spacer are disconnected between the sub-pixels.

9. The electroluminescent display device of claim 4, further comprising: a second hydrogen adsorption layer disposed on the bank in the non-emission area other than an area in which the first hydrogen adsorption layer and the spacer are disposed.

10. The electroluminescent display device of claim 9, wherein the first hydrogen adsorption layer and the second hydrogen adsorption layer are made of Ti or a Ti alloy of Ti/Al/Ti.

11. The electroluminescent display device of claim 9, wherein the first hydrogen adsorption layer and the second hydrogen adsorption layer are made of any one metal comprising at least one of Sc, V, Pd, Nb, Zr, Y, Ta, Ce, La, Sm, and U.

12. The electroluminescent display device of claim 5, wherein the planarization layer includes,
a first planarization layer disposed on the oxide thin film transistor; and
a second planarization layer disposed on the first planarization layer.

13. The electroluminescent display device of claim 12, further comprising: an intermediate electrode disposed on the first planarization layer and electrically connecting the anode and the oxide thin film transistor.

14. The electroluminescent display device of claim 13, wherein the intermediate electrode is made of Ti or a Ti alloy of Ti/Al/Ti.

15. The electroluminescent display device of claim 13, wherein the intermediate electrode is made of any one metal comprising at least one of Sc, V, Pd, Nb, Zr, Y, Ta, Ce, La, Sm, and U.

16. The electroluminescent display device of claim 12, wherein the second planarization layer in the non-emission area is removed to thereby form a second groove,
wherein the electroluminescent display device further includes a second hydrogen adsorption layer disposed on an inner surface of the second groove.

17. The electroluminescent display device of claim 16, wherein the second groove is configured by removing the second planarization layer in the non-emission area other than an area in which the anode, the first hydrogen adsorption layer, and the intermediate electrode are disposed.

18. The electroluminescent display device of claim 16, wherein the first groove and the second groove have a “U″-shape and have a taper in which a side surface thereof is inclined outwardly in an upward direction.

19. The electroluminescent display device of claim 18, wherein the first hydrogen adsorption layer and the second hydrogen adsorption layer have a “U″-shape, and have a taper in which the side surface thereof is inclined outwardly in the upward direction.

20. The electroluminescent display device of claim 16, wherein the bank is disposed on the second hydrogen adsorption layer to fill an inside of the second groove.

21. The electroluminescent display device of claim 1, wherein the bank further includes a non-opening portion covering a portion of the anode and the planarization layer,
wherein the first hydrogen adsorption layer is disposed in the non-opening portion of the bank.

22. The electroluminescent display device of claim 21, further comprising: a second hydrogen adsorption layer configured to have a greater area or a greater depth than that of the first hydrogen adsorption layer.

23. The electroluminescent display device of claim 12, further comprising: a third groove provided by removing a partial region of the second planarization layer of the sub-pixel,
wherein the anode is disposed on an inner surface of the third groove.

24. The electroluminescent display device of claim 23, wherein the third groove has a “U″-shape and has a taper in which a side surface thereof is inclined outwardly in an upward direction.

25. An electroluminescent display device, comprising:
a thin film transistor disposed above a substrate;
a planarization layer disposed above the thin film transistor;
an anode layer disposed above the planarization layer;
a bank layer disposed above the planarization layer, the bank layer including an opening that exposes a portion of the anode layer;
a light emitting structure disposed above the exposed portion of the anode layer; and
a first hydrogen adsorption layer disposed between the exposed portion of the anode layer and the thin film transistor.

26. The electroluminescent display device of claim 25, wherein:
the first hydrogen adsorption layer is arranged between the light emitting structure and the thin film transistor.

27. The electroluminescent display device of claim 25, wherein:
the first hydrogen adsorption layer is electrically connected to a drain electrode of the thin film transistor.

28. The electroluminescent display device of claim 25, wherein:
the first hydrogen adsorption layer comprises one of Ti or a Ti alloy.

29. The electroluminescent display device of claim 25, further comprising:
a second hydrogen adsorption layer disposed above the planarization layer.

30. The electroluminescent display device of claim 29, wherein:
the substrate is divided into a plurality of sub-pixels having an emission area and a non-emission area, the second hydrogen adsorption layer is disposed above the planarization layer in the non-emission area.

31. The electroluminescent display device of claim 30, wherein:
the second hydrogen adsorption layer is disposed between at least two of the plurality of sub-pixels.

32. The electroluminescent display device of claim 30, wherein:
the light emitting structure is disposed above the anode layer in the emission area.

33. The electroluminescent display device of claim 25, wherein:
the thin film transistor comprises an oxide thin film transistor.
